(19) United States
(12) Patent Application Publication
(10) Pub. No.: US 2026/0282695 A1
(43) Pub. Date: Sep. 17, 2026

(54) ELECTRONIC DEVICE AND METHOD OF MANUFACTURING THE SAME

(71) Applicant: Samsung Display Co., Ltd., Yongin-si (KR)

(72) Inventors: Kyuwon Cho, Yongin-si (KR); Yun-Hee Park, Yongin-si (KR); Jina Seo, Yongin-si (KR); Yiseop Shim, Yongin-si (KR); Yun Ho Lee, Yongin-si (KR); Hyunseung Lee, Yongin-si (KR)

(21) Appl. No.: 19/390,328

(22) Filed: Nov. 14, 2025

(30) Foreign Application Priority Data
Mar. 12, 2025 (KR) 10-2025-0032342

(51) Int. Cl. H10K 59/38; H10K 59/12; H10K 59/80

(52) U.S. Cl. CPC H10K 59/38; H10K 59/1201; H10K 59/873

(57) ABSTRACT

Disclosed is an electronic device including a display panel and an optical layer on the display panel. The optical layer may include a green filter including a green pigment. The green pigment may include a particle of which a surface is encapsulated, and the particle may include a phthalocyanine (PC)-based pigment including a metal element at a center thereof. The electronic device according to an embodiment may exhibit excellent light resistance and excellent color reproducibility.

### CROSS-REFERENCE TO RELATED APPLICATION

The present application claims priority to and the benefit of Korean Patent Application No. 10-2025-0032342, filed on Mar. 12, 2025, in the Korean Intellectual Property Office, the entire content of which is hereby incorporated by reference.

### BACKGROUND

### 1. Technical Field

Embodiments of the present disclosure described herein relate to an electronic device including a green filter and a method of manufacturing an electronic device.

### 2. Description of the Related Art

Various display devices used in multimedia devices such as televisions, mobile phones, tablet computers, and game consoles have been developed. The display device may include an optical member to provide an image having excellent quality to a user. Research on optical members to improve display quality and display efficiency in various types or kinds of display devices has been conducted.

### SUMMARY

Embodiments of the present disclosure provide an electronic device having improved light resistance and improved color reproducibility.

Embodiments of the present disclosure also provide a method of manufacturing an electronic device exhibiting excellent processability.

According to an embodiment, an electronic device includes a display panel and an optical layer on the display panel, wherein the optical layer includes a green filter including a green pigment, the green pigment includes a particle of which a surface is encapsulated, and the particle is a phthalocyanine (PC)-based pigment including a metal element at a center thereof.

Luminance of the electronic device after 80 hours of light exposure may be greater than or equal to 99% based on 100% initial luminance.

A diameter of the green pigment may be smaller than or equal to 1 μm.

The surface of the particle may be encapsulated by an organic layer, an inorganic layer, or an organic-inorganic multi-layer structure.

The particle may include at least one selected from pigment green 7, pigment green 36, pigment green 58, and pigment green 59.

The metal element may include at least one selected from copper and zinc.

The optical layer may further include a pattern part in which a first pattern opening, a second pattern opening, and a third pattern opening are defined, a red filter provided in the first pattern opening, and a blue filter provided in the third pattern opening, and the green filter may be provided in the second pattern opening.

The optical layer may further include an overcoat layer on the red filter, the green filter, and the blue filter.

The electronic device may further include an input sensing layer between the display panel and the optical layer.

The display panel may include a light emitting element, and the light emitting element may include a first electrode, a second electrode on the first electrode, and a light emitting layer between the first electrode and the second electrode.

The electronic device may further include at least one selected from a processor, a memory, and a power module.

According to an embodiment, a method of manufacturing an electronic device includes preparing a display panel and providing an optical layer including a green filter on the display panel, wherein the providing of the optical layer includes forming a pattern part in which a pattern opening is defined, providing a filter composition including a green pigment into the pattern opening, and forming the green filter by curing the provided filter composition, the green pigment includes a particle of which a surface is encapsulated, and the particle is a phthalocyanine (PC)-based pigment including a metal element at a center thereof.

The green filter may be formed by an inkjet printing method.

The filer composition may not contain a solvent.

A diameter of the green pigment may be smaller than or equal to a 1 μm.

The green pigment may be formed in an emulsion polymerization method, a sol-gel process method using a micelle-silica precursor, or a ball-mill method.

The surface of the particle may be encapsulated by an organic layer, an inorganic layer, or an organic-inorganic multi-layer structure.

The particle may include at least one selected from pigment green 7, pigment green 36, pigment green 58, and pigment green 59.

The filter composition may further include at least one selected from a binder, a monomer, a radical initiator, and an additive.

The additive may include at least one selected from a fluorine additive and a surfactant.

### BRIEF DESCRIPTION OF THE DRAWINGS

The above and other objects and features of embodiments of the present disclosure will become apparent by describing in more detail embodiments thereof with reference to the accompanying drawings.

FIG. 1 is a perspective view illustrating an electronic device according to an embodiment.

FIG. 2 is an exploded perspective view illustrating the electronic device according to an embodiment.

FIG. 3A is a perspective view illustrating the electronic device according to an embodiment.

FIG. 3B is a perspective view illustrating the electronic device according to an embodiment.

FIG. 3C is a plan view illustrating the electronic device according to an embodiment.

FIG. 3D is a perspective view illustrating the electronic device according to an embodiment.

FIG. 4 is an exploded perspective view illustrating the electronic device according to an embodiment.

FIG. 5 is a cross-sectional view illustrating a portion corresponding to line I-I′ of FIG. 4.

FIG. 6 is a cross-sectional view of a portion of the electronic device according to an embodiment.

FIG. 7A is a schematic view illustrating a green pigment according to an embodiment.

FIG. 7B is a schematic view illustrating the green pigment according to an embodiment.

FIG. 8 is a cross-sectional view of a portion of the electronic device according to an embodiment.

FIG. 9A is a schematic view illustrating an operation of manufacturing a green pigment according to an embodiment.

FIG. 9B is a schematic view illustrating an operation of manufacturing a green pigment according to an embodiment.

FIG. 10A is a flowchart illustrating a method of manufacturing an electronic device according to an embodiment.

FIG. 10B is a flowchart illustrating the method of manufacturing an electronic device according to an embodiment.

FIG. 11A is a schematic view illustrating an operation of manufacturing an electronic device according to an embodiment.

FIG. 11B is a schematic view illustrating the operation of manufacturing an electronic device according to an embodiment.

FIG. 11C is a schematic view illustrating the operation of manufacturing an electronic device according to an embodiment.

FIG. 12 is a block diagram of an electronic device according to an embodiment.

FIG. 13 is a schematic view illustrating electronic devices according to an embodiment.

### DETAILED DESCRIPTION

In the specification, the expression that a first component (or area, layer, part, portion, and/or the like) is “on”, “connected with” or “coupled to” a second component means that the first component is directly on/connected with/coupled to the second component or means that a third component is interposed therebetween.

The same reference numerals refer to the same components. Further, in the drawings, the thickness, the ratio, and the dimension of components may be exaggerated for effective description of technical contents. The expression “and/or” includes one or more combinations which associated components are capable of defining.

Although the terms “first,” “second,” and/or the like, may be used to describe various components, the components should not be limited by the terms. The terms are used only to distinguish one component, one part, one area, one layer or one portion from another component, another part, another area, another layer or another portion. For example, without departing from the scope of the present disclosure, a first component, a first part, a first area, a first layer, or a first portion may be referred to as a second component, a second part, a second area, a second layer, or a second portion, and similarly, the second component, the second part, the second area, the second layer, or the second portion may also be referred to as the first component, the first part, the first area, the first layer, or the first portion. Singular expressions include plural expressions unless clearly otherwise indicated in the context.

Also, the terms “under”, “below”, “on”, “above”, and/or the like are used to describe the correlation of components illustrated in drawings. The terms that are relative in concept are described based on a direction illustrated in the drawings.

It will be understood that the terms “include”, “comprise”, “have”, and/or the like specify the presence of features, numbers, steps, operations, elements, or components, described in the specification, or a combination thereof, and do not exclude in advance the presence or additional possibility of one or more other features, numbers, steps, operations, elements, or components or a combination thereof.

Unless otherwise defined, all terms (including technical terms and scientific terms) used in the specification have the same meaning as commonly understood by those skilled in the art to which the present disclosure belongs. Furthermore, terms such as terms defined in dictionaries commonly used should be interpreted as having a meaning consistent with the meaning in the context of the related technology and should not be interpreted in overly ideal or overly formal meanings unless explicitly defined herein.

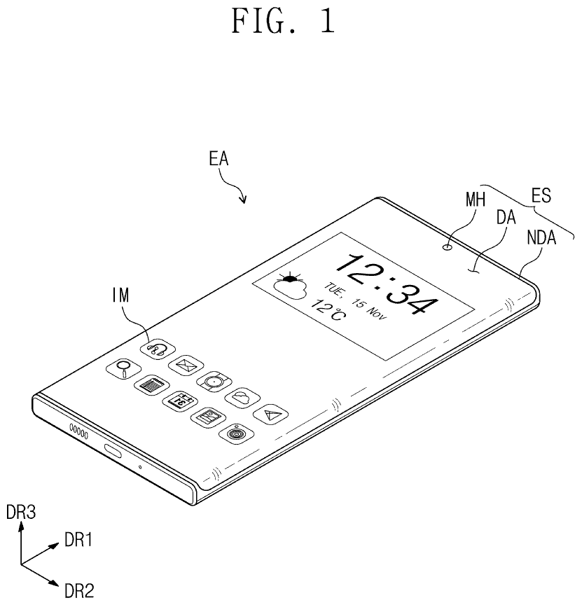

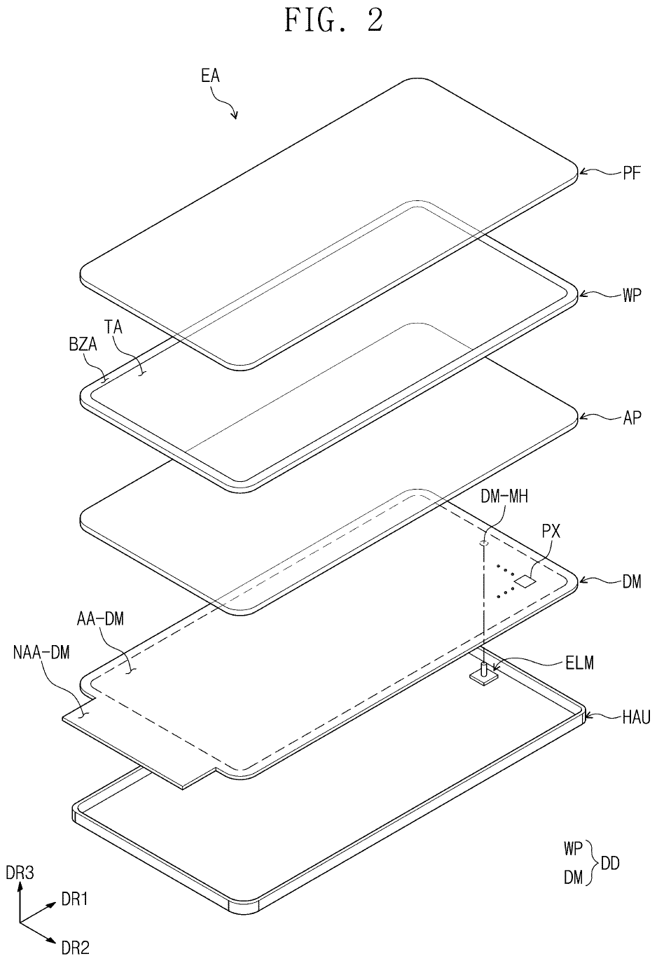

Hereinafter, an electronic device according to an embodiment of the present disclosure will be described with reference to the accompanying drawings. FIG. 1 is a perspective view illustrating an electronic device according to an embodiment. FIG. 2 is an exploded perspective view of an electronic device according to an embodiment.

An electronic device EA according to an embodiment illustrated in FIG. 1 may be a device that is activated according to an electrical signal. Examples of the electronic device EA may include a personal computer, a laptop computer, a personal digital terminal, a game console, a portable electronic device, a television, a monitor, an external billboard, a vehicle navigation system, and/or a wearable device, but an embodiment is not limited thereto. FIG. 1 illustrates, by way of example, that the electronic device EA is a smart phone, but the present disclosure is not limited thereto.

The electronic device EA may include a display surface ES defined by a first direction axis DR1 and a second direction axis DR2 crossing the first direction axis DR1. The electronic device EA may provide an image IM to a user through the display surface ES. The electronic device EA may display the image IM in a third direction axis DR3 to the display surface ES parallel (e.g., substantially parallel) to the first direction axis DR1 and the second direction axis DR2. The image IM may include a dynamic image and/or a static image.

The directions indicated by the first direction axis DR1, the second direction axis DR2, and the third direction axis DR3 described in the specification are relative concepts and may be changed to other directions. Further, the directions indicated by the first direction axis DR1, the second direction axis DR2, and the third direction axis DR3 may be described as a first direction, a second direction, and a third direction, and the same reference numerals may be used therefor.

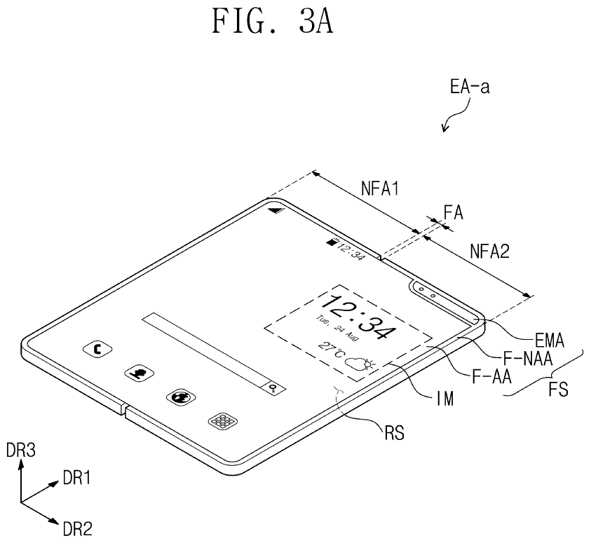

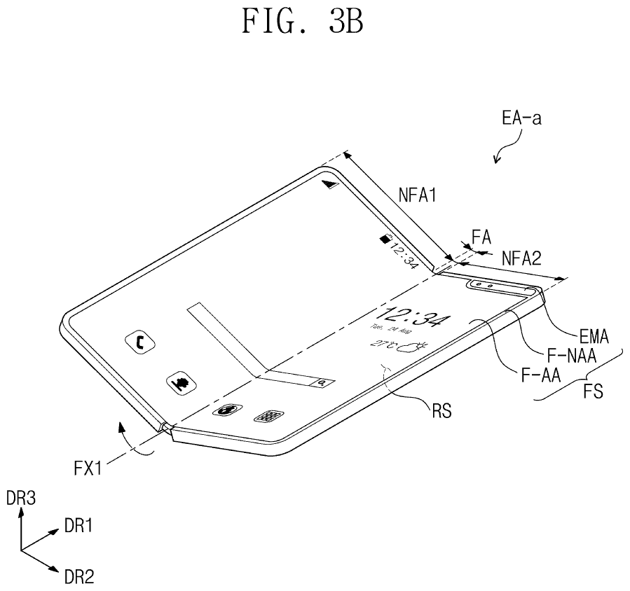

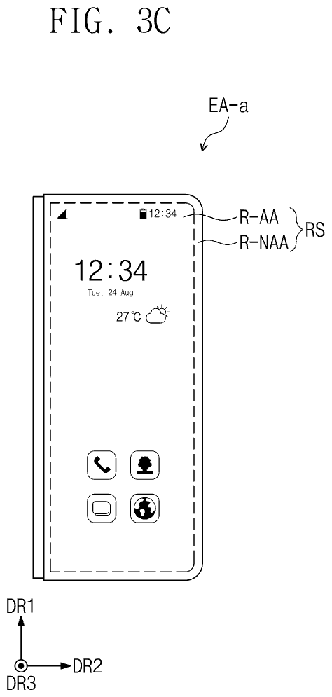

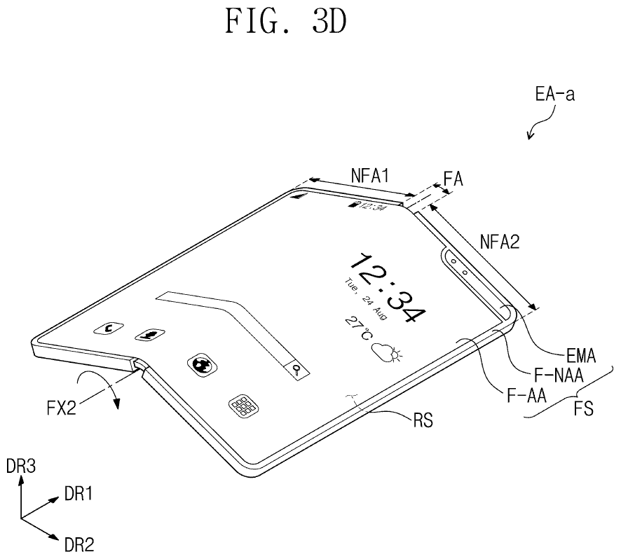

In the specification, the first direction axis DR1 and the second direction axis DR2 may be perpendicular (e.g., substantially perpendicular) to each other, and the third direction axis DR3 may be a normal direction to a plane defined by the first direction axis DR1 and the second direction axis DR2. A thickness direction of the electronic device EA may be a direction parallel (e.g., substantially parallel) to the third direction axis DR3. The thickness direction of the electronic device EA may use the same reference numeral as that of the third direction axis DR3. A front surface (or an upper surface) and a rear surface (or a lower surface) may be opposite to each other in the third direction axis DR3, and a normal direction of each of the front surface (or the upper surface) and the rear surface (or the lower surface) may be parallel (e.g., substantially parallel) to the third direction axis DR3. The front surface (or the upper surface) means a surface adjacent to the display surface ES, and the rear surface (or the lower surface) means a surface spaced apart from the display surface ES. Further, the rear surface (or the lower surface) means a surface close to a second display surface RS (FIG. 3A), which will be further described herein below. An upper side means a direction closer to the display surface ES, and a lower side means a direction away from the display surface ES.

In the specification, a cross section means a surface parallel (e.g., substantially parallel) to the thickness direction DR3, and a plane means a surface perpendicular (e.g., substantially perpendicular) to the thickness direction DR3. A plane means a surface parallel (e.g., substantially parallel) to the plane defined by the first direction axis DR1 and the second direction axis DR2.

In the specification, the wording “substantially the same” includes a case in which physical values are the same and a case in which there is a difference within an error range in a process.

The electronic device EA may sense an external input applied from the outside. The external input may include various suitable types or kinds of inputs provided from the outside of the electronic device EA. For example, the external input may include a contact by a part of a body of the user such as a hand as well as an external input (for example, hovering) applied close to the electronic device EA and/or adjacent to the electronic device EA at a set or selected distance. Further, the external input may have various suitable forms such as a force, a pressure, a temperature, and/or light.

The display surface ES may include a display area DA, a non-display area NDA, and a sub-area MH. The display area DA may be an area that is activated according to an electric signal. The display area DA may be an area in which the image IM may be displayed and various suitable forms of external inputs may be sensed.

The display area DA may include the plane defined by the first direction axis DR1 and the second direction axis DR2. The display area DA may include a curved surface bent from at least one side of the plane defined by the first direction axis DR1 and the second direction axis DR2. In the electronic device EA illustrated in FIG. 1, it is illustrated that the display area DA includes two curved surfaces bent from both sides of the plane defined by the first direction axis DR1 and the second direction axis DR2. However, the foregoing is by way of example, and a shape of the display area DA is not limited thereto. For example, the display area DA may include only the plane defined by the first direction axis DR1 and the second direction axis DR2, and the display area DA may further include four curved surfaces bent from at least two, e.g., four side surfaces of the plane defined by the first direction axis DR1 and the second direction axis DR2.

The electronic device EA according to an embodiment may be flexible. As used herein, the wording “flexible” may mean a property that may be bent and include both a structure that is completely folded and a structure that may be bent by several nanometers. For example, the electronic device EA may be a rigid device. In embodiments, the electronic device EA may be a foldable device.

The non-display area NDA may have a color. The non-display area NDA may be an area adjacent to the display area DA. The non-display area NDA may surround the display area DA. Accordingly, a shape of the display area DA may be substantially defined by the non-display area NDA. However, this is illustrated by way of example, and the non-display area NDA may be adjacent to only one side of the display area DA or may be omitted. The display area DA may be provided in various suitable shapes, and the present disclosure is not limited thereto.

The sub-area MH may sense an external subject received through the display surface ES or provide a sound signal such as voice to the outside through the display surface ES. An optical signal such as visible light and/or infrared light may be moved to the sub-area MH. The sub-area MH may be inside the display area DA. However, the foregoing is by way of example, and the arrangement of the sub-area MH is not limited to an embodiment. For example, the sub-area MH may be surrounded by the non-display area NDA or may be surrounded by the display area DA and the non-display area NDA. FIG. 1 illustrates one sub-area MH, but the sub-area MH may be provided as a plurality of sub-areas MH.

Various suitable electronic modules ELM (see FIG. 2) may correspond to the sub-area MH. For example, the electronic module ELM (see FIG. 2) may include at least one selected from a camera, a speaker, a light sensing sensor, and a heat sensing sensor. The electronic device EA may include the electronic module ELM (see FIG. 2) that captures an external image through visible light passing through the sub-area MH and/or determines accessibility of an external object utilizing infrared light. The electronic module ELM (see FIG. 2) may include a plurality of components, and is not limited to an embodiment.

Referring to FIG. 2, the electronic device EA may include a display device DD and the electronic module ELM. The display device DD may include a display module DM and a window WP on the display module DM. The electronic device EA may further include a housing HAU, an adhesive layer AP, and a protective layer PF. A module area DM-MH may be defined in the display device DD, and the electronic module ELM may correspond to the module area DM-MH.

In the electronic device EA illustrated in FIGS. 1 and 2, the housing HAU may be provided under the display module DM. The housing HAU may include a material having a relatively high rigidity. For example, the housing HAU may include a plurality of frames and/or plates made of glass, plastic (e.g., polymer), and/or metal. The display module DM may be accommodated in the housing HAU. The housing HAU may provide an accommodation space. The display module DM may be accommodated inside the accommodation space and protected from an external impact.

The adhesive layer AP may be on the display module DM. The display module DM and the window WP may be coupled to each other by the adhesive layer AP. The adhesive layer AP may be an optically transparent area. For example, the adhesive layer AP may include a pressure sensitive adhesive (PSA), an optically clear adhesive film (OCA), and/or an optically clear adhesive resin layer (OCR).

The protective layer PF may be on the window WP. The protective layer PF may be a functional layer that protects one surface (e.g., an upper surface) of the window WP. For example, the protective layer PF may include polyethylene terephthalate (PET). The protective layer PF may include a fingerprint preventing coating agent, a static preventing agent, a hard coating agent, and/or the like.

The display module DM may be activated by an electrical signal. The display module DM may be activated to display the image IM (FIG. 1) on the display area DA (see FIG. 1) of the electronic device EA. An active area AA-DM, a peripheral area NAA-DM, and the module area DM-MH may be defined in the display module DM.

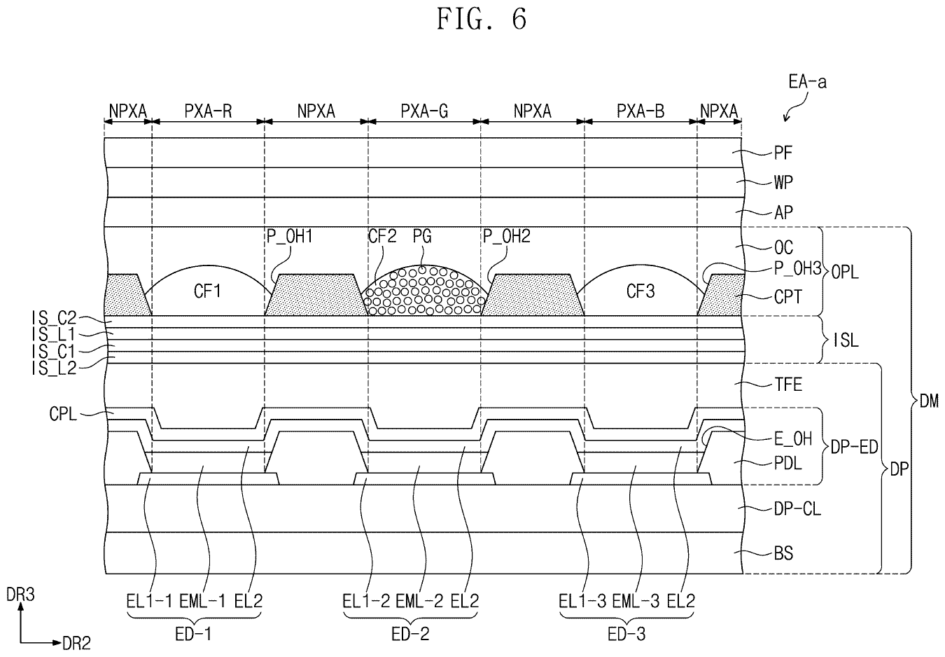

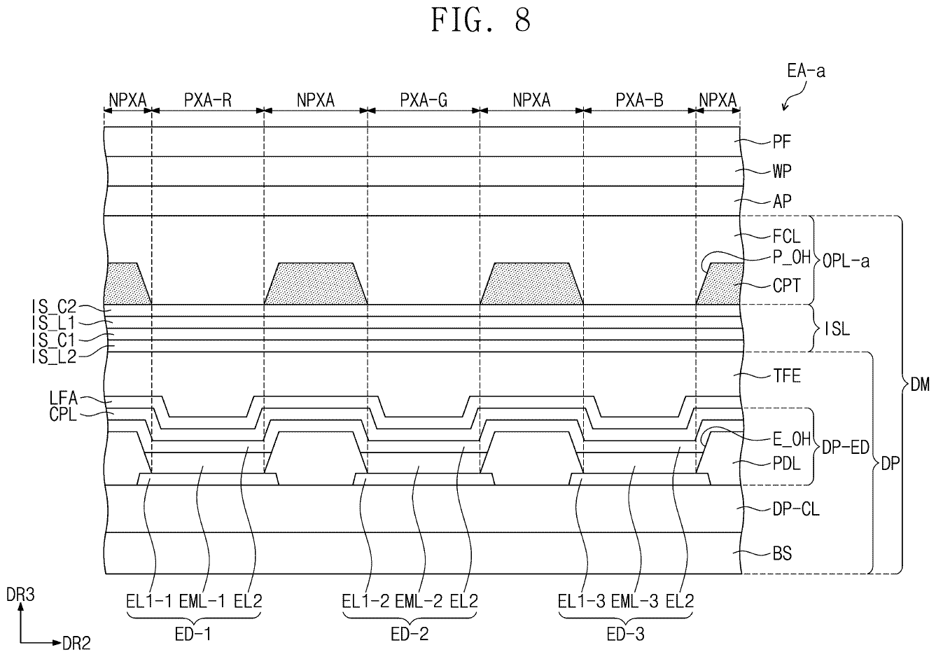

The active area AA-DM may be an area that is activated according to an electrical signal. A pixel PX may be provided in the active area AA-DM. The pixel PX may include a transistor and light emitting elements ED-1, ED-2, and ED-3 (see FIGS. 6 and 8). The peripheral area NAA-DM may be an area adjacent to at least one side of the active area AA-DM. A circuit, a wiring line, and/or the like for driving the active area AA-DM may be provided in the peripheral area NAA-DM.

The module area DM-MH may correspond to the sub-area MH illustrated in FIG. 1. An optical signal such as visible light and/or infrared light may be moved to the module area DM-MH. The module area DM-MH may be provided in the active area AA-DM. In embodiments, the module area DM-MH may be surrounded by the peripheral area NAA-DM or may be surrounded by the active area AA-DM and the peripheral area NAA-DM. A position of the module area DM-MH is not limited to an embodiment.

The electronic module ELM may be an electronic component that outputs and/or receives an optical signal. For example, the electronic module ELM may include a camera module and/or a proximity sensor. The camera module may capture an external image through the module area DM-MH.

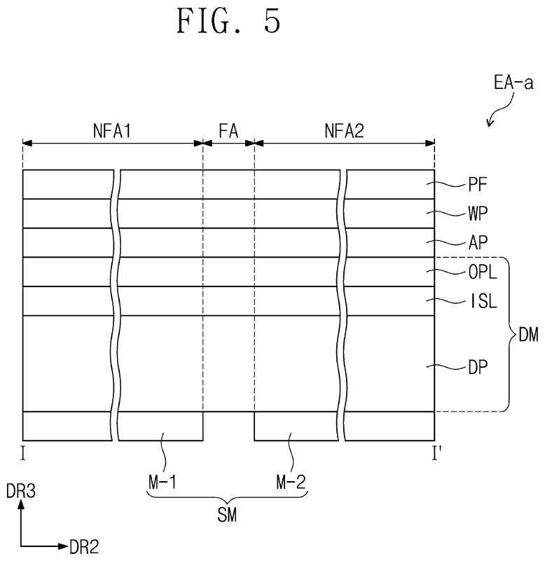

The display device DD may include an optical layer OPL (see FIGS. 5 and 6) between the display module DM and the window WP. The optical layer OPL (see FIGS. 5 and 6) may be formed on the display module DM through a continuous (e.g., substantially continuous) process. The optical layer OPL (see FIGS. 5 and 6) may include a color filter layer. The optical layer OPL (see FIGS. 5 and 6) may include a plurality of color filters CF1, CF2, and CF3 (see FIG. 6) provided in a selected arrangement. For example, the color filters CF1, CF2, and CF3 (see FIG. 6) may be provided in consideration of light emitting colors of the pixels PX. Further, the optical layer OPL (see FIGS. 5 and 6) may further include a black matrix adjacent to the color filters CF1, CF2, and CF3 (see FIG. 6).

The window WP may include a transmissive area TA and a bezel area BZA. The transmissive area TA may overlap at least a portion of the active area AA-DM of the display module DM. The transmissive area TA may be an optically transparent area. The image IM (see FIG. 1) may be provided to the user through the transmissive area TA. For example, the window WP may include ultra thin glass (UTG).

The bezel area BZA may be an area having a relatively low light transmittance as compared to the transmissive area TA. The bezel area BZA may define a shape of the transmissive area TA. The bezel area BZA may be adjacent to the transmissive area TA and surround the transmissive area TA.

The bezel area BZA may have a color. The bezel area BZA may cover the peripheral area NAA-DM of the display module DM and prevent or reduce visual recognition of the peripheral area NAA-DM from the outside. However, an embodiment is not limited to the illustration, and the bezel area BZA may be adjacent to only one side of the transmissive area TA or at least a portion thereof may be omitted.

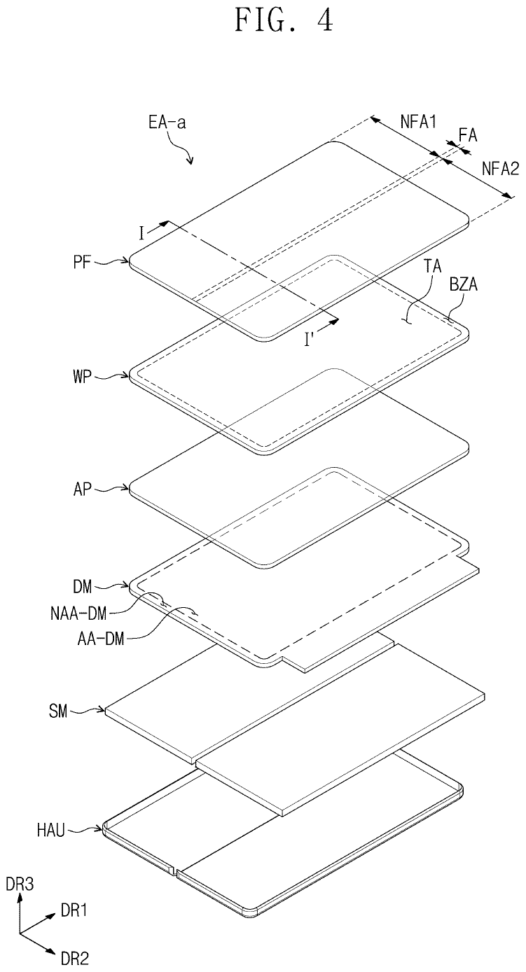

FIGS. 3A to 3D and 4 are views illustrating an electronic device EA-a according to an embodiment of the present disclosure. Hereinafter, in the description of FIGS. 3A to 3D and 4, contents duplicated with the contents described with reference to FIGS. 1 and 2 may not be described again, and differences therebetween will be mainly described.

The electronic device EA-a illustrated in FIGS. 3A to 3D and 4 may be a device that is foldable based on at least one folding axis FX1 and FX2. FIG. 3A is a perspective view illustrating an unfolded state of the electronic device EA-a according to an embodiment.

The electronic device EA-a may include a first display surface FS and the second display surface RS. The first display surface FS may include a first display area F-AA, a first non-display area F-NAA, and an electronic module area EMA. The second display surface RS may be defined as a surface facing at least a portion of the first display surface FS. For example, the second display surface RS may be defined as a portion of the rear surface of the electronic device EA-a.

The first display area F-AA may be an area that is activated according to an electrical signal. The first display area F-AA may be an area in which the image IM may be displayed and various suitable forms of external inputs may be sensed. The first non-display area F-NAA may be adjacent to the first display area F-AA. The first non-display area F-NAA may have a color. The first non-display area F-NAA may surround the first display area F-AA. Accordingly, a shape of the first display area F-AA may be defined substantially by the first non-display area F-NAA. However, the foregoing is by way of example, and the first non-display area F-NAA may be adjacent to only one side of the first display area F-AA or may be omitted.

The electronic module area EMA may be surrounded by the first non-display area F-NAA. However, the foregoing is by way of example, and the present disclosure is not limited to an embodiment. For example, the electronic module area EMA may be surrounded by the first display area F-AA and the first non-display area F-NAA, and the electronic module area EMA may be inside the first display area F-AA.

The electronic device EA-a may include at least one folding area FA and a plurality of non-folding areas NFA1 and NFA2 extending from the folding area FA. For example, the first non-folding area NFA1, the folding area FA, and the second non-folding area NFA2 may be defined in the second direction DR2. The electronic device EA-a may include the folding area FA maybe between the first non-folding area NFA1 and the second non-folding area NFA2 in the second direction DR2. For example, the first non-folding area NFA1 may be on one side of the folding area FA in the second direction DR2, and the second non-folding area NFA2 may be on the other side of the folding area FA in the second direction DR2.

FIG. 3A illustrates the electronic device EA-a including the one folding area FA according to an embodiment, but an embodiment is not limited thereto, and a plurality of folding areas may be defined in the electronic device EA-a. For example, the electronic device according to an embodiment may include two or more folding areas and may include three or more non-folding areas provided with the folding areas interposed therebetween.

FIG. 3B is a perspective view illustrating a folding operation of the electronic device EA-a according to an embodiment. FIG. 3C is a plan view of a state in which the electronic device EA-a according to an embodiment is folded. FIG. 3D is a perspective view illustrating the folding operation of the electronic device EA according to an embodiment.

Referring to FIG. 3B, the electronic device EA-a according to an embodiment may be folded about the first folding axis FX1 extending in the first direction DR1. In a state in which the electronic device EA-a is folded, the folding area FA may have a selected curvature and a selected radius of curvature. The electronic device EA-a may be folded about the first folding axis FX1 so that the first non-folding area NFA1 and the second non-folding area NFA2 face each other and may be changed into an in-folding state to prevent or reduce exposure of the first display surface FS to the outside.

Referring to FIG. 3C, in a state in which the electronic device EA-a according to an embodiment is in an in-folding state, the second display surface RS may be visually recognized by the user. In embodiments, the second display surface RS may include a second display area R-AA that displays an image. The second display area R-AA may be an area that is activated according to an electrical signal. The second display area R-AA may be an area on which an image may be displayed and various suitable types or kinds of external inputs may be sensed.

A second non-display area R-NAA may be adjacent to the second display area R-AA. The second non-display area R-NAA may have a color. The second non-display area R-NAA may surround the second display area R-AA. Further, in embodiments, the electronic device EA-a may further include an electronic module area in which an electronic module including various suitable components is on the second display surface RS, but the present disclosure is not limited to an embodiment.

Referring to FIG. 3D, the electronic device EA-a according to an embodiment may be folded about the second folding axis FX2 extending in the first direction DR1. The electronic device EA-a may be folded about the second folding axis FX2 and changed into an out-folding state so that the first display surface FS is exposed to the outside. The electronic device EA-a according to an embodiment may be configured to mutually repeat an in-folding operation or an out-folding operation from an unfolding operation, but the present disclosure is not limited thereto.

FIGS. 3A to 3D illustrate, by way of example, the folding about the one folding axis FX1 or FX2, but the number of folding axes and the number of non-folding areas according thereto are not limited thereto. For example, the electronic device EA-a may be folded about a plurality of folding axes so that the first display surface FS and the second display surface RS are folded to partially face each other. Further, it is illustrated that the first folding axis FX1 and the second folding axis FX2 are parallel (e.g., substantially parallel) to long sides of the electronic device EA-a, but an embodiment is not limited thereto, and the first folding axis FX1 and the second folding axis FX2 may be parallel (e.g., substantially parallel) to short sides of the electronic device EA-a.

In the electronic device EA-a, as illustrated in FIG. 3C, the first non-folding area NFA1 and the second non-folding area NFA2 may be defined as portions having the display surfaces FS and RS parallel (e.g., substantially parallel) to the plane defined by the first direction axis DR1 and the second direction axis DR2 in a folded state, and the folding area FA may be defined as an area between the first non-folding area NFA1 and the second non-folding area NFA2. The folding area FA may include a curved surface that is curved to have a slight curvature in a folded state.

FIG. 4 is an exploded perspective view illustrating the electronic device EA-a illustrated in FIG. 3A. Hereinafter, in description of FIG. 4, contents duplicated with the contents described with reference to FIGS. 1 to 3D may not be described again, and differences therebetween will be mainly described.

Referring to FIG. 4, the electronic device EA-a according to an embodiment may include the display module DM, the window WP on the display module DM, and the adhesive layer AP between the display module DM and the window WP. Further, the electronic device EA-a according to an embodiment may further include a support member SM provided under the display module DM, the protective layer PF on the window WP, and the housing HAU accommodating the display module DM and the support member SM.

The support member SM may include a metal material and/or a polymer material. For example, the support member SM may be formed to include stainless steel, aluminum, and/or an alloy thereof. Further, in embodiments, the support member SM may be formed of carbon fiber reinforced plastic (CFRP) and/or the like. However, an embodiment is not limited thereto, and the support member SM may include a nonmetallic material, plastic (e.g., polymer), glass fiber reinforced plastic, and/or glass. Unlike the illustration, the support member SM may be omitted.

In embodiments, the electronic device EA-a may further include a cushion layer, a shielding layer, and/or the like provided under the support member SM. The cushion layer may include an elastomer such as sponge, foam, and/or urethane resin. The shielding layer may be an electromagnetic wave shielding layer and/or a heat dissipating layer.

FIG. 5 is a cross-sectional view illustrating a portion corresponding to line I-I′ of FIG. 4. FIG. 5 may be a cross-sectional view illustrating the electronic device EA-a according to an embodiment. Hereinafter, in description of FIG. 5, contents duplicated with the contents described with reference to FIGS. 1 to 4 may not be described again, and differences therebetween will be mainly described.

The display module DM may be configured to generate an image and sense input applied from the outside. The display module DM may include a display panel DP and the optical layer OPL on the display panel DP. Further, the display module DM may further include an input sensing layer ISL between the display panel DP and the optical layer OPL.

The display panel DP may be a component that substantially generates an image. The display panel DP may be a light emitting display panel, and for example, the display panel DP may be an organic light emitting display panel, an inorganic light emitting display panel, a quantum dot display panel, a micro light emitting diode (LED) display panel, and/or a nano LED display panel. The display panel DP may be referred to as a display layer.

The input sensing layer ISL may be on the display panel DP. For example, the input sensing layer ISL may be directly on an encapsulation layer TFE (see FIGS. 6 and 8) of the display panel DP. The input sensing layer ISL may sense an external input, change the sensed external input into a selected input signal, and provide the input signal to the display panel DP. For example, in the electronic device EA-a according to an embodiment, the input sensing layer ISL may be a touch sensing layer that senses a touch. The input sensing layer ISL may recognize a direct touch of the user, an indirect touch of the user, a direct touch of an object, and/or an indirect touch of the object.

The input sensing layer ISL may sense at least one of a position and a strength (pressure) of a touch applied from the outside. The input sensing layer ISL may have various suitable structures and/or be formed of various suitable materials, and the present disclosure is not limited to an embodiment. For example, the input sensing layer ISL may sense an external input in a capacitive manner. The display panel DP may receive the input signal from the input sensing layer ISL and generate an image corresponding to the input signal.

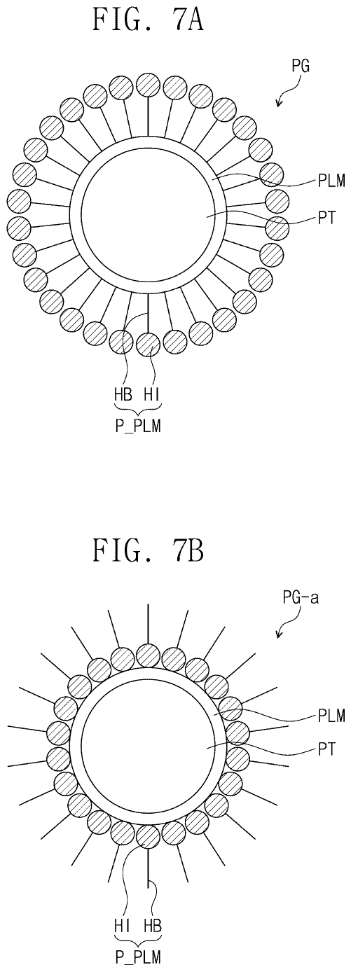

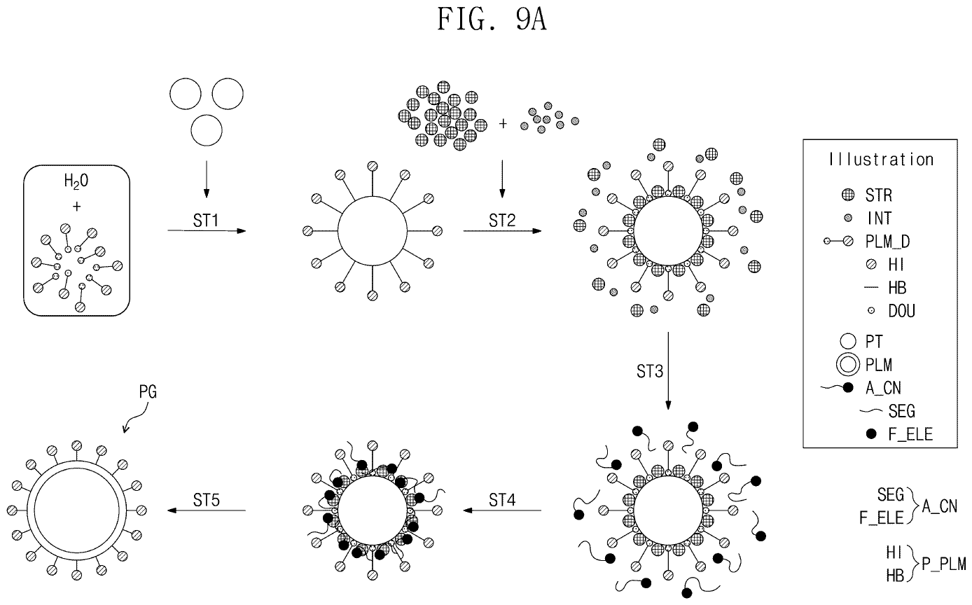

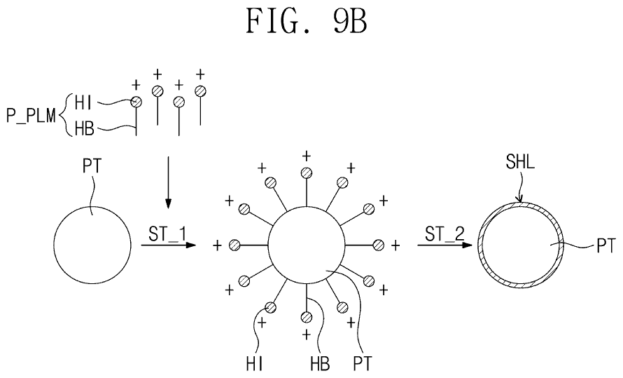

The optical layer OPL may be on the input sensing layer ISL. The optical layer OPL may include a pigment. The optical layer OPL may further include a dye. The optical layer OPL may be a layer that selectively transmits light emitted from the display panel DP. The optical layer OPL may be a layer that reduces reflectance of external light incident from the outside. The optical layer OPL may include a green filter CF2 (see FIG. 6) including a green pigment PG (see FIGS. 6, 7A, and 9A), the green pigment may include particles PT (see FIGS. 7A, 9A, and 9B) of which surfaces are encapsulated, and the particles may include a phthalocyanine (PC)-based pigment including a metal element at a center thereof. The electronic device EA-a including the optical layer OPL according to an embodiment may exhibit excellent light resistance and excellent color reproducibility.

The support member SM may include a first support M-1 and a second support M-2 spaced apart from each other in the second direction DR2. The first support M-1 may correspond to the first non-folding area NFA1, and the second support M-2 may correspond to the second non-folding area NFA2. The first support M-1 and the second support M-2 may not overlap the folding area FA. However, an embodiment is not limited thereto, and portions of the first support M-1 and the second support M-2 may overlap the folding area FA. The support member SM may include a metal material, a polymer material, a non-metal material, plastic, glass fiber reinforced plastic, and/or glass.

In embodiments, the electronic device EA-a may further include a module protecting layer between the display module DM and the support member SM. Further, the electronic device EA-a may further include the cushion layer provided under the support member SM. However, the foregoing is by way of example, and a component provided under the display module DM is not limited thereto. The component provided under the display module DM may further include an additional support plate, an additional adhesive layer, and/or the like according to a size, a shape, and/or operation characteristics of the electronic device EA-a.

The module protecting layer may be a layer provided under the display module DM to protect a rear surface of the display module DM. The module protecting layer may overlap the entire display module DM. The module protecting layer may include a polymer material. For example, the module protecting layer may be a polyimide film and/or a polyethylene terephthalate film.

FIG. 6 is a cross-sectional view illustrating the display module DM, the adhesive layer AP, the window WP, and the protective layer PF of FIG. 5. Further, FIG. 6 is a cross-sectional view illustrating the display panel DP, the input sensing layer ISL, and the optical layer OPL in more detail. Hereinafter, in description of FIG. 6, contents duplicated with the contents described with reference to FIGS. 1 to 5 may not be described again, and differences therebetween will be mainly described.

Referring to FIG. 6, the display panel DP may include a base layer BS, a circuit layer DP-CL on the base layer BS, a display element layer DP-ED on the circuit layer DP-CL, and the encapsulation layer TFE on the display element layer DP-ED. The base layer BS may be a member that provides a base surface on which

the display element layer DP-ED is provided. The base layer BS may be a glass substrate, a metal substrate, a polymer substrate, and/or the like. However, an embodiment is not limited thereto, and the base layer BS may be an inorganic layer, an organic layer, or a composite material layer including an inorganic material and an organic material.

The base layer BS may include a single layer or a plurality of layers. For example, the base layer BS may include a first synthetic resin layer, a multi-layered or single-layered inorganic layer, and a second synthetic resin layer on the multi-layered or single-layered inorganic layer. Each of the first synthetic resin layer and the second synthetic resin layer may include a polyimide-based resin. Further, each of the first synthetic resin layer and the second synthetic resin layer may include at least one selected from an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. In the specification, a “~~-based” resin means a resin including a functional group of “~~.”

The circuit layer DP-CL may include an insulating layer (e.g., an electrically insulating layer), a semiconductor pattern, a conductive pattern (e.g., an electrically conductive pattern), a signal line, and/or the like. The circuit layer DP-CL may include a plurality of transistors. Each of the transistors may include a control electrode, an input electrode, and an output electrode. For example, the circuit layer DP-CL may include a switching transistor and a driving transistor for driving components (e.g., a first electrode, a light emitting layer, and a second electrode) of the display element layer DP-ED.

The display element layer DP-ED may include a pixel defining film PDL and light emitting elements ED-1, ED-2, and ED-3, in which a pixel opening E_OH is defined. The light emitting elements ED-1, ED-2, and ED-3 may include first electrodes EL1-1, EL1-2, and EL1-3 exposed in the pixel opening E_OH, light emitting layers EML-1, EML-2, and EML-3 on the first electrodes EL1-1, EL1-2, and EL1-3, and second electrodes EL2 on the light emitting layers EML-1, EML-2, and EML-3.

The display panel DP may be divided into light emitting areas PXA-R, PXA-G, and PXA-B and a non-light emitting area NPXA. The light emitting areas PXA-R, PXA-G, and PXA-B may be spaced apart from each other on a plane. The light emitting areas PXA-R, PXA-G, and PXA-B may be areas through which light generated by the display element layer DP-ED is output. The light emitting areas PXA-R, PXA-G, and PXA-B may include the red light emitting area PXA-R, the green light emitting area PXA-G, and the blue light emitting area PXA-B, which are distinguished from each other. Each of the light emitting areas PXA-R, PXA-G, and PXA-B may be an area divided by the pixel defining film PDL. The non-light emitting areas NPXA may be areas between the neighboring light emitting areas PXA-R, PXA-G, and PXA-B and may be areas corresponding to the pixel defining film PDL.

The pixel defining film PDL may have a property of absorbing light. The pixel defining film PDL may include a black coloring agent. The black coloring agent may include a black dye and/or a black pigment. The black coloring agent may include carbon black, a metal such as chromium, and/or an oxide thereof. The pixel defining film PDL may cover portions of the first electrodes EL1-1, EL1-2, and EL1-3. In the specification, a state in which a first component overlaps a second component is not limited to a state in which the first component and the second component have the same area and the same shape and includes a state in which the first component and the second component have different areas and/or different shapes.

The first electrodes EL1-1, EL1-2, and EL1-3 may be anodes or cathodes. Further, the first electrodes EL1-1, EL1-2, and EL1-3 may be pixel electrodes. The first electrodes EL1-1, EL1-2, and EL1-3 may be a transmissive electrode, a semi-transmissive electrode, or a reflective electrode. If (e.g., when) the first electrodes EL1-1, EL1-2, and EL1-3 are transmissive electrodes, the first electrodes EL1-1, EL1-2, and EL1-3 may include a transparent metal oxide, for example, an indium tin oxide (ITO), an indium zinc oxide (IZO), a zinc oxide (ZnO), an indium tin zinc oxide (ITZO), and/or the like. If (e.g., when) the first electrodes EL1-1, EL1-2, and EL1-3 are semi-transmissive electrodes or reflective electrodes, the first electrodes EL1-1, EL1-2, and EL1-3 may include Ag, Mg, Cu, Al, Pt, Pd, Au, Ni, Nd, Ir, Cr, Li, Ca, LiF/Ca, LiF/Al, Mo, Ti, W, and/or a compound and/or mixture thereof (e.g., a mixture of Ag and Mg). In embodiments, the first electrodes EL1-1, EL1-2, and EL1-3 may have a multi-layer structure including a reflective film or a semi-transmissive film formed of the above material and a transparent conductive film formed of an indium tin oxide (ITO), an indium zinc oxide (IZO), a zinc oxide (ZnO), and/or an indium tin zinc oxide (ITZO). For example, the first electrodes EL1-1, EL1-2, and EL1-3 may have a three-layer structure of ITO/Ag/ITO, but the present disclosure is not limited thereto.

The display element layer DP-ED may include the plurality of light emitting layers EML-1, EML-2, and EML-3. Each of the light emitting layers EML-1, EML-2, and EML-3 may be patterned and provided inside the pixel opening E_OH defined in the pixel defining film PDL. The light emitting layers EML-1, EML-2, and EML-3 may overlap the light emitting areas PXA-R, PXA-G, and PXA-B. The display element layer DP-ED may include the first light emitting layer EML-1 corresponding to the first light emitting area PXA-R, the second light emitting layer EML-2 corresponding to the second light emitting area PXA-G, and the third light emitting layer EML-3 corresponding to the third light emitting area PXA-B. Each of the light emitting layers EML-1, EML-2, and EML-3 may emit light having different wavelength areas. For example, the first light emitting layer EML-1 may emit red light, the second light emitting layer EML-2 may emit green light, and the third light emitting layer EML-3 may emit blue light.

Each of the light emitting layers EML-1, EML-2, and EML-3 may include an organic light emitting material and/or an inorganic light emitting material. For example, each of the light emitting layers EML-1, EML-2, and EML-3 may include a fluorescent and/or phosphorescent material. Each of the light emitting layers EML-1, EML-2, and EML-3 may include an anthracene derivative, a pyrene derivative, a fluorantene derivative, a chrycene derivative, a dihydrobenzanthracene derivative, and/or a triphenylene derivative. Further, the light emitting layers EML-1, EML-2, and EML-3 may include a metal organic complex as a light emitting material. The light emitting layers EML-1, EML-2, and EML-3 may include quantum dots as light emitting materials.

Each of the light emitting layers EML-1, EML-2, and EML-3 may be provided in a single layer or a plurality of layers. For example, if (e.g., when) the first light emitting layer EML-1 is provided in a plurality of layers, a charge generating layer (not illustrated) may be between the plurality of first light emitting layers EML-1. However, the foregoing is by way of example, and an embodiment is not limited thereto.

The second electrode EL2 may be a common electrode. The second electrode EL2 may be a cathode or an anode, but an embodiment is not limited thereto. For example, if (e.g., when) the first electrodes EL1-1, EL1-2, and EL1-3 are anodes, the second electrode EL2 may be a cathode, or if (e.g., when) the first electrodes EL1-1, EL1-2, and EL1-3 are cathodes, the second electrode EL2 may be an anode.

The second electrode EL2 may be a transmissive electrode, a semi-transmissive electrode or a reflective electrode. If (e.g., when) the second electrode EL2 is a transmissive electrode, the second electrode EL2 may be formed of a transparent metal oxide, for example, an indium tin oxide (ITO), an indium zinc oxide (IZO), a zinc oxide (ZnO), an indium tin oxide (ITZO), and/or the like.

In embodiments, a hole transport area (not illustrated) may be between the first electrodes EL1-1, EL1-2, and EL1-3 and the light emitting layers EML-1, EML-2, and EML-3, and the hole transport area may include at least one selected from a hole transport layer, a hole injection layer, and an electron blocking layer. Further, an electron transport area is between the light emitting layers EML-1, EML-2, and EML-3 and the second electrode EL2, and the electron transport area may include at least one selected from an electron transport layer, an electron injection layer, and a hole blocking layer. The hole transport area and the electron transport area may be provided as a common layer or patterned and provided in the pixel opening E_OH.

The display element layer DP-ED may further include a capping layer CPL on the second electrode EL2. The capping layer CPL may include a single layer or a plurality of layers. The capping layer CPL may include an organic material and/or an inorganic material. In an embodiment, the capping layer CPL may be an organic layer and/or an inorganic layer. For example, if (e.g., when) the capping layer CPL includes an inorganic material, the inorganic material may include an alkali metal compound such as LiF, an alkaline earth metal compound such as MgF₂, a silicon oxy nitride, a silicon nitride, a silicon oxide, and/or the like. For example, if (e.g., when) the capping layer CPL includes an organic material, the organic material may include α-NPD, NPB, TPD, m-MTDATA, Alq3, CuPc, TPD15 (N4,N4,N4′,N4′-tetra(biphenyl-4-yl)biphenyl-4,4′-diamine), TCTA (4,4′,4″-Tris(carbazol-9-yl)triphenylamine), and/or the like and/or may include an acrylate such as an epoxy resin and/or a methacrylate.

A refractive index of the capping layer CPL may be 1.6 or higher. For example, the refractive index of the capping layer CPL for light having a wavelength area of 550 nm to 660 nm may be 1.6 or higher. The capping layer CPL may improve optical efficiency by the principle of constructive interference.

The encapsulation layer TFE may seal the display element layer DP-ED. The encapsulation layer TFE may include at least one inorganic layer (hereinafter, referred to as an inorganic encapsulation film). Further, the encapsulation layer TFE may include at least one organic film (hereinafter, an organic encapsulation film) and at least one inorganic encapsulation film. The inorganic encapsulation film may protect the display element layer DP-ED from moisture/oxygen, and the organic encapsulation film may protect the display element layer DP-ED from foreign substances such as dust particles. The inorganic encapsulation film may include a silicon nitride, a silicon oxy nitride, a silicon oxide, a titanium oxide, and/or an aluminum oxide, but the present disclosure is not particularly limited thereto. The organic encapsulation film may include an acryl-based compound, an epoxy-based compound, and/or the like. The organic encapsulation film may include an organic material capable of photopolymerization, and the present disclosure is not particularly limited thereto.

The input sensing layer ISL may include a base insulating layer IS_L2 (e.g., an electrically insulating layer), a first conductive layer IS_C1 (e.g., an electrically conductive layer) on the base insulating layer IS_L2, a second conductive layer IS_C2 (e.g., an electrically conductive layer) on the first conductive layer IS_C1, and a touch insulating layer IS_L1 (e.g., an electrically insulating layer) between the first conductive layer IS_C1 and the second conductive layer IS_C2. The base insulating layer IS_L2 may include a single layer or a plurality of layers. The base insulating layer IS_L2 may include an organic material and/or an inorganic material. The base insulating layer IS_L2 may include at least one selected from a silicon nitride, a silicon oxy nitride, and a silicon oxide. In embodiments, the base insulating layer IS_L2 may include an epoxy resin, an acrylic resin, and/or an imide-based resin.

The touch insulating layer IS_L1 may include an organic material and/or an inorganic material. For example, the touch insulating layer IS_L1 may include at least one selected from an epoxy-based resin, a urethane-based resin, a cellulose-based resin, a siloxane-based resin, a polyimide-based resin, a polyamide-based resin, and a perylene-based resin. In embodiments, the touch insulating layer IS_L1 may include at least one selected from an aluminum oxide, a titanium oxide, a silicon oxide, a silicon nitride, a silicon oxy nitride, a zirconium oxide, and a hafnium oxide.

Each of the first conductive layer IS_C1 and the second conductive layer IS_C2 may include a single layer or a plurality of layers. Each of the first conductive layer IS_C1 and the second conductive layer IS_C2 may include a metal layer and/or a transparent conductive layer as a single layer. The metal layer may include molybdenum (Mo), silver (Ag), titanium (Ti), copper (Cu), aluminum (AI), and/or an alloy thereof. The transparent conductive layer may include a transparent conductive oxide such as an indium tin oxide (ITO), an indium zinc oxide (IZO), and/or an indium tin oxide (ITZO). Further, the transparent conductive layer may include a conductive polymer (e.g., an electrically conductive polymer) such as poly(3,4-ethylenedioxythiophene) (PEDOT), metal nanowires, graphene, and/or the like.

In embodiments, each of the first conductive layer IS_C1 and the second conductive layer IS_C2 may include at least one metal layer and at least one transparent conductive layer (e.g., transparent electrically conductive layer). For example, each of the first conductive layer IS_C1 and the second conductive layer IS_C2 may have a three-layer structure of ITO/Ag/ITO.

The optical layer OPL may include a pattern part CPT, a red filter CF1, the green filter CF2, and a blue filter CF3. The pattern part CPT may define a first pattern opening P_OH1, a second pattern opening P_OH2, and a third pattern opening P_OH3. The first pattern opening P_OH1, the second pattern opening P_OH2, and the third pattern opening P_OH3 may be spaced apart from each other in the second direction DR2 perpendicular (e.g., substantially perpendicular) to the thickness direction DR3. The red filter CF1 may be provided in the first pattern opening P_OH1. The green filter CF2 may be provided in the second pattern opening P_OH2. The blue filter CF3 may be provided in the third pattern opening P_OH3. Further, the optical layer OPL may further include an overcoat layer OC on the pattern part CPT, the red filter CF1, the green filter CF2, and the blue filter CF3.

A material constituting the pattern part CPT is not particularly limited as long as the material absorbs light. The pattern part CPT may have a black color, and the pattern part CPT may include a black coloring agent. The black coloring agent may include a black dye and a black pigment. The black coloring agent may include carbon black, a metal such as chromium, and/or an oxide thereof.

The red filter CF1, the green filter CF2, and the blue filter CF3 may correspond to the light emitting layers EML-1, EML-2, and EML-3. The optical layer OPL may include the red filter CF1 corresponding to the first light emitting layer EML-1, the green filter CF2 corresponding to the second light emitting layer EML-2, and the blue filter CF3 corresponding to the third light emitting layer EML-3. Each of the red filter CF1 and the blue filter CF3 may include a pigment and/or a dye. The green filter CF2 may not include a dye. If (e.g., when) the green filter includes a dye, a low-viscosity monomer that dissolves the dye is necessarily required. Thus, the green filter including the dye may exhibit low manufacturing efficiency during an inkjet printing process. Further, the green filter including the dye may exhibit low reliability. Accordingly, the optical layer OPL including the red filter CF1, the green filter CF2, and the blue filter CF3 may improve display quality of the electronic device EA-a.

In an embodiment, the green filter CF2 may include the green pigment PG including the particles PT (see FIGS. 7A, 9A, and 9B) of which surfaces are encapsulated. The particles PT (see FIGS. 7A, 9A, and 9B) may be a phthalocyanine (PC)-based pigment including a metal element at a center thereof. If (e.g., when) the particles are the phthalocyanine (PC)-based pigment not including a metal element at a center thereof, introduction of a reactor capable of curing the particles under ultraviolet and/or thermal conditions may be required or utilized. Thus, the green filter including the particles not including a metal element in a center thereof may exhibit low manufacturing efficiency during a manufacturing process. Unlike this, the electronic device EA-a including the green filter CF2 according to an embodiment may exhibit excellent light resistance and excellent color reproducibility.

The overcoat layer OC may cover the pattern part CPT, the red filter CF1, the green filter CF2, and the blue filter CF3. The overcoat layer OC may include an organic material. The overcoat layer OC may be a flattening layer.

FIGS. 7A and 7B schematically illustrate green pigments PG and PG-a included in the green filter CF2 (see FIG. 6) according to an embodiment. Referring to FIG. 7A, the green filter CF2 (see FIG. 6) according to an embodiment may include the green pigment PG including the particles PT, a coating layer PLM, and a coating agent P_PLM.

The particles PT may be a phthalocyanine (PC)-based pigment including a metal element at a center thereof. For example, the particles PT may include phthalocyanine green 7, phthalocyanine green 36, and/or diketopyrrolopyrrole (DPP). The metal element may include at least one selected from copper and zinc. Surfaces of the particles PT may be encapsulated with the coating layer PLM. Further, the coating agent P_PLM may be on the coating layer PLM.

In the green pigment PG according to an embodiment, the surfaces of the particles PT may be completely encapsulated by an organic layer, an inorganic layer, or an organic-inorganic multi-layer structure. In the green pigment PG of which a surface is completely encapsulated, contact of a metal element at a center of the particles PT with an outgas generated during light exposure may be prevented or reduced. As the coating layer PLM is present between the metal element and the outgas, contact between the metal element and the outgas may be prevented or reduced.

The coating layer PLM may be a layer surrounding the surfaces of the particles PT. The layer surrounding the surfaces of the particles PT may be an organic layer, an inorganic layer, or an organic-inorganic multi-layer structure. For example, the organic layer may include, as an organic material, a polymer such as polyurethane, polystyrene, and/or epoxy resin and/or a surfactant such as sulfate ester and/or polyethylene glycol (PEG). For example, the inorganic layer may include an inorganic material such as a silica (SiO₂), a titanium oxide (TiO₂), an aluminum oxide (alumina, Al₂O₃), and/or a calcium carbonate (CaCO₃). For example, the organic-inorganic multi-layer structure may be a layer formed by chemically or physically combining an organic material and an inorganic material or a laminated structure in which an organic layer and an inorganic layer are alternately laminated. The organic-inorganic multi-layer structure may be a combination of an acryl-based resin and a silica (SiO₂), a combination of polyurethane and a titanium oxide (titania, TiO₂), a combination of an epoxy resin and an aluminum oxide (alumina, Al₂O₃), and/or the like. However, the foregoing is by way of example, and an embodiment is not limited thereto.

Referring to FIG. 7A, the coating agent P_PLM may be a surfactant including a hydrophilic part HI and a hydrophobic part HB. The coating agent P_PLM may surround the coating layer PLM in the form of a micelle or a reverse micelle.

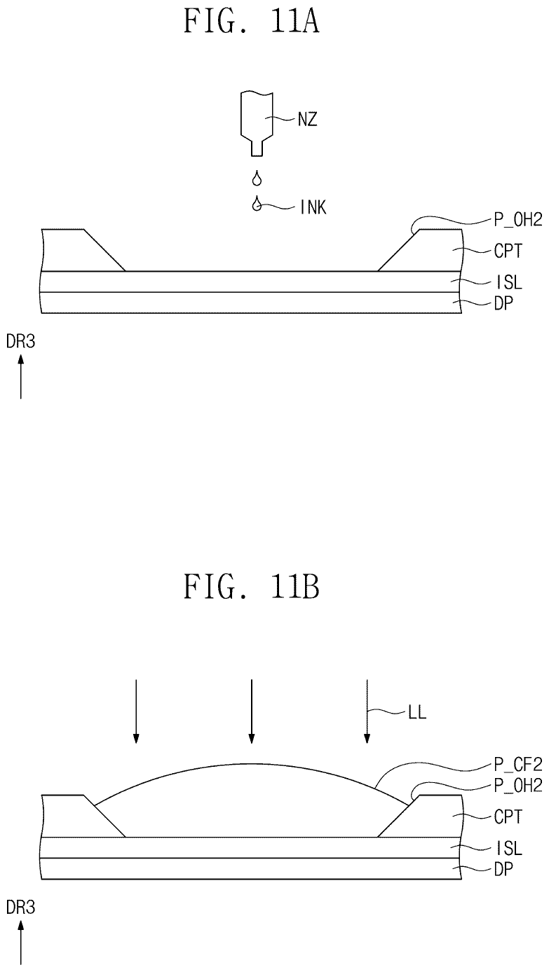

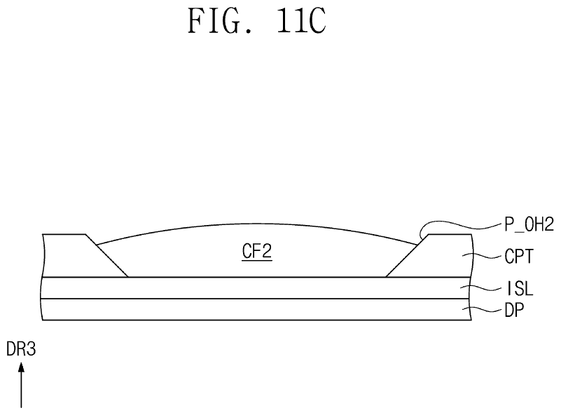

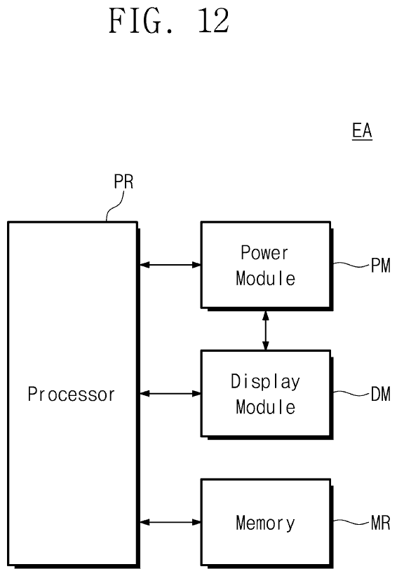

The green pigment PG may have a diameter of 1 μm or less. For example, the diameter of the green pigment PG may be 0.2 μm or less. A filter composition IK (see FIG. 11A) including the green pigment PG having a diameter of 1 μm or less may exhibit excellent discharge properties.

The particles PT may include at least one selected from pigment green 7, pigment green 36, pigment green 58, and pigment green 59. The pigment green 7, the pigment green 36, the pigment green 58, and the pigment green 59 are phthalocyanine pigments.

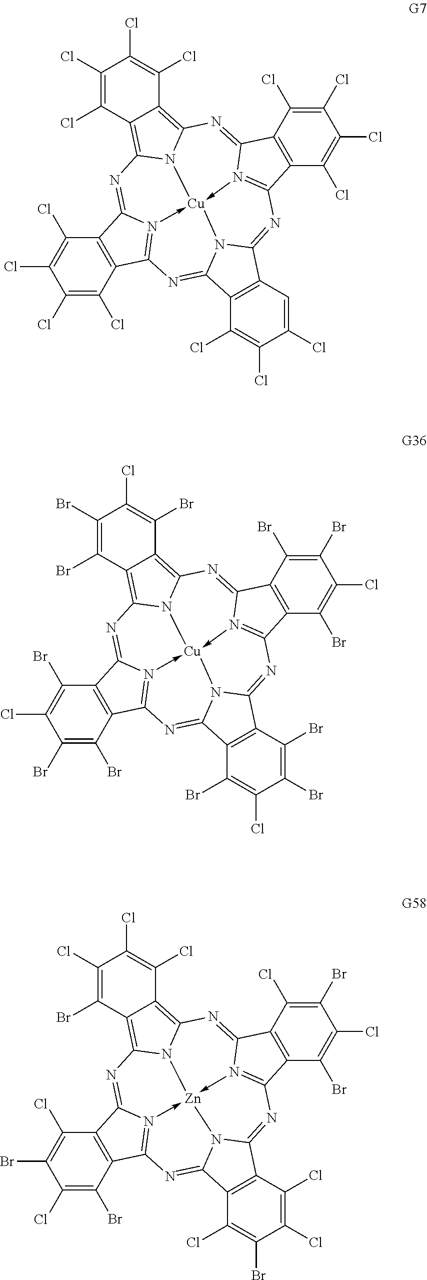

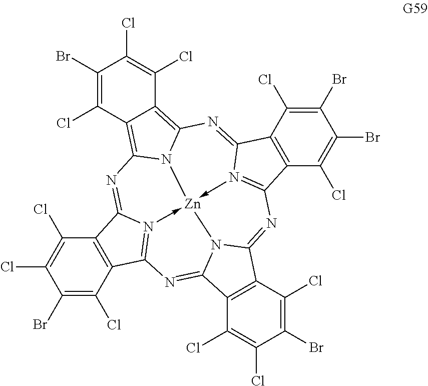

G7 represents a structural formula of the pigment green 7. The pigment green 7 is obtained by replacing a terminal hydrogen atom of pigment blue 15 with a chlorine atom (Cl), and a central metal thereof is copper. G36 represents a structural formula of the pigment green 36. The pigment green 36 is obtained by replacing 12 of 16 terminal chlorine atoms (Cl) of the pigment green 7 with bromine atoms (Br), and a central metal thereof is copper. G58 represents a structural formula of pigment green 58. Pigment green 58 is obtained by replacing 6 of 16 terminal chlorine atoms (Cl) of the pigment green 7 with bromine atoms (Br), and a central metal thereof is zinc. G59 represents a structural formula of pigment green 59. Pigment green 59 is obtained by replacing four of six terminal bromine atoms (Br) of pigment green 58 with chlorine atoms (Cl), and a central metal thereof is zinc.

The electronic device EA-a (see FIG. 6) including the green pigment PG according to an embodiment may have a luminance of 99% or more after 80 hours of light exposure based on 100% initial luminance. The light may be visible light having a wavelength range of 380 nm to 780 nm. Contact between the outgas generated during the light exposure and the metal element included in the green pigment PG is prevented or reduced, and thus luminance degradation may not occur even if (e.g., when) a light exposure time is accumulated or increased. Accordingly, the electronic device EA-a including the green pigment PG according to an embodiment may exhibit excellent light resistance and excellent color reproducibility.

Table 1 below represents luminance measured in the electronic device according to Embodiment and Comparative Example. The luminance is measured by the CI 3000 (product made by Atlas).

Table 1 represents initial luminance Y₁ according to Embodiments and Comparative Examples and luminance Y₂ after 80 hours of light exposure under 420 nm and 1.4 W conditions and represents luminance % Y after 80 hours of light exposure based on 100% initial luminance. In Table 1, x₁, x₂, y₁, and y₂ are coordinate values defining a position of a color in the CIE 1931 chromaticity. Embodiment 1 (E1) and Embodiment 2 (E2) are each an electronic device according to an embodiment. The green pigment used in the electronic device according to an embodiment is obtained by encapsulating a surface of a particle in a sol-gel process method using a micelle-silica precursor.

TABLE 1

| Electronic | Green | Initial time | | | 10 cycles (80 hours) | | | Change amount | | |
|---|---|---|---|---|---|---|---|---|---|---|
| device | pigment | Y₁ | x₁ | y₁ | Y₂ | x₂ | y₂ | % Y | Δx | Δy |
| E1 | Encapsulated | 41.59 | 0.1892 | 0.7527 | 41.50 | 0.1889 | 0.7527 | 99.80% | 0.0000 | 0.0000 |
| | G7 | | | | | | | | | |
| E2 | Encapsulated | 41.45 | 0.1885 | 0.7531 | 41.40 | 0.1883 | 0.7531 | 99.88% | 0.0000 | 0.0000 |
| | G36 | | | | | | | | | |
| CE1 | G7 | 40.56 | 0.1865 | 0.7542 | 36.35 | 0.1842 | 0.7546 | 89.60% | −0.0020 | 0.0000 |
| CE2 | G36 | 40.95 | 0.1865 | 0.7545 | 36.34 | 0.1842 | 0.7547 | 88.80% | −0.0020 | 0.0000 |

### E: Embodiment, CE: Comparative Example

Referring to Table 1, the electronic device according to Embodiment 1 includes the pigment green 7 of which a surface is encapsulated. The electronic device according to Embodiment 2 includes the pigment green 36 of which a surface is encapsulated. The electronic devices according to each of Embodiment 1 and Embodiment 2 has luminance of 99% or more after 80 hours of light exposure based on 100% initial luminance. Thus, it may be seen that the electronic device according to an embodiment exhibits excellent light resistance and excellent color reproducibility.

The electronic device according to Comparative Example 1 includes the pigment green 7 of which the surface is not encapsulated. The electronic device according to Comparative Example 2 includes the pigment green 36 of which the surface is not encapsulated. The electronic device according to Comparative Example 1 and Comparative Example 2 has luminance of 99% or less after 80 hours of light exposure based on 100% initial luminance.

The electronic device according to each of Comparative Example 1 and Comparative Example 2 includes particles of which surfaces are not encapsulated, and thus a metal element at a center of a particle and a non-covalent electron pair present in the outgas generated during light exposure form a coordination bond. If (e.g., when) the metal element and the non-covalent electron pair form a coordination bond (e.g., a coordinate covalent bond or dative bond), the luminance is decreased. Thus, the electronic device according to Comparative Example 1 and Comparative Example 2 exhibits low luminance after light exposure.

FIG. 7B is a cross-sectional view illustrating an embodiment of the present disclosure, and the green pigment PG-a of FIG. 7B differs from the green pigment PG illustrated in FIG. 7A in that a portion thereof in contact with the coating layer PLM is the hydrophilic part HI of the coating agent P_PLM.

FIG. 8 is a cross-sectional view illustrating an embodiment of the present disclosure, and an optical layer OPL-a of FIG. 8 differs from the optical layer OPL illustrated in FIG. 6 in that the former includes a light control layer FCL instead of the red filter CF1, the green filter CF2, and the blue filter CF3. Further, FIG. 8 illustrates that a low reflective layer LFA is further between the display element layer DP-ED and the encapsulation layer TFE. Hereinafter, in description of FIG. 8, contents duplicated with the contents described with reference to FIGS. 1 to 7D may not be described again, and differences therebetween will be mainly described.

Referring to FIG. 8, the light control layer FCL may fill a pattern opening P_OH and may be on the pattern part CPT. The light control layer FCL may be a flattening layer. The light control layer FCL may be a reflection preventing layer that reduces reflectance of external light incident from the outside. The light control layer FCL may be a layer that selectively transmits light emitted from the display panel DP. The light control layer FCL may include a pigment and/or a dye. A pigment and a dye included in the light control layer FCL may be materials that transmit only light having a set or specific wavelength range among light emitted from the display element layer DP-ED. Accordingly, the optical layer OPL-a including the light control layer FCL may improve display quality and light efficiency of the electronic device EA-a.

The light control layer FCL according to an embodiment may include the green pigment PG (see FIG. 7A) of which the surface is encapsulated. In the light control layer FCL according to an embodiment, an unreacted pigment and/or an unreacted dye in the light control layer FCL may be eluted to prevent or reduce staining of the adhesive layer AP on the light control layer FCL. Accordingly, the electronic device EA-a including the light control layer FCL according to an embodiment may exhibit improved transmittance (e.g., light transmittance).

The low reflective layer LFA may be on the display element layer DP-ED. For example, the low reflective layer LFA may be on the capping layer CPL or the capping layer CPL may be omitted and the low reflective layer LFA may be on the second electrode EL2. The low reflective layer LFA may include an inorganic material having a low reflectivity, and may include a metal and/or a metal oxide. For example, the low reflective layer LFA may include ytterbium (Yb), bismuth (Bi), cobalt (Co), molybdenum (Mo), titanium (Ti), zirconium (Zr), aluminum (AI), chromium (Cr), niobium (Nb), platinum (Pt), tungsten (W), indium (In), tin (Sn), iron (Fe), nickel (Ni), tantalum (Ta), manganese (Mn), zinc (Zn), germanium (Ge), silver (Ag), magnesium (Mg), gold (Au), copper (Cu), calcium (Ca), or a combination thereof. In embodiments, the low reflective layer LFA may include, for example, SiO₂, TiO₂, ZrO₂, Ta₂O₅, HfO₂, Al₂O₃, ZnO, Y₂O₃, BeO, MgO, PbO₂, WO₃, SiNₓ, LiF, CaF₂, MgF₂, CdS, or a combination thereof.

The low reflective layer LFA may have an absorption coefficient k of 1.5 or less. For example, the absorption coefficient of the low reflective layer LFA may be greater than 0.5 and smaller than or equal to 1.5. The low reflective layer LFA having an absorption coefficient greater than 0.5 and smaller than or equal to 1.5 may reduce reflectance of light.

The low reflective layer LFA induces extinction interference between light incident into the electronic device EA-a and light reflected from a metal (e.g., a second electrode) provided under the low reflective layer LFA, thereby reducing reflectance of external light. Accordingly, display quality and light efficiency of the electronic device EA-a including the low reflective layer LFA may be improved.

The green pigment according to an embodiment may be manufactured by a method of manufacturing a green pigment according to an embodiment. For example, the green pigment may be manufactured in an emulsion polymerization method, a sol-gel process method using a micelle-silica precursor, and/or a ball-mill method. FIGS. 9A and 9B are schematic views illustrating an operation of manufacturing a green pigment according to an embodiment. Hereinafter, in description of FIGS. 9A and 9B, contents duplicated with the contents described with reference to FIGS. 1 to 8 may not be described again, and differences therebetween will be mainly described.

FIG. 9A illustrates an operation of encapsulating the surface of the particle by an emulsion polymerization method. The green pigment PG manufactured from the manufacturing operation of FIG. 9A may be obtained by encapsulating the surfaces of the particles PT with an organic layer.

In FIG. 9A, “ST1” may indicate an operation of providing the particles PT to water (H₂O) containing a dispersant PLM_D. The dispersant PLM_D may include the hydrophilic part HI, the hydrophobic part HB, and a double bond part DOU. The double bond part DOU may be spaced apart from the hydrophilic part HI and provided at an end of the hydrophobic part HB. The hydrophobic part HB of the dispersant PLM_D is coupled to the particles PT through the double bond part DOU, and the hydrophilic part HI of the dispersant PLM_D interacts with water, so that the particles PT may be uniformly (e.g., substantially uniformly) dispersed in the water.

“ST2” may indicate an operation of providing styrene STR and an initiator INT to the water in which the particles PT are dispersed. The styrene STR, which is a hydrophobic molecule, may form an emulsion layer on the surfaces of the particles PT.

“ST3” may indicate an operation of forming an active polymer chain A_CN from the styrene STR and the initiator INT. The active polymer chain A_CN may include a polymerization part SEG and a free electron F_ELE. The free electron F_ELE may be maintained in an active state so that the polymerization part SEG of the active polymer chain A_CN may react with the styrene STR at an end of the active polymer chain A_CN.

“ST4” may indicate an operation of adsorbing the active polymer chain A_CN to the styrene STR in which the emulsion layer is formed on the surfaces of the particles PT. “ST5” may indicate an operation of encapsulating the surfaces of the particles PT into the coating layer PLM while the active polymer chain A_CN adsorbed on the styrene STR is continuously (e.g., substantially continuously) polymerized by a radical reaction.

FIG. 9B indicates an operation of encapsulating the surfaces of the particles by a sol-gel process method using a micelle-silica precursor. The green pigment PG manufactured from the manufacturing operation of FIG. 9B may be obtained by encapsulating the surfaces of the particles PT in an organic-inorganic multi-layer structure.

In FIG. 9B, “ST_1” may indicate an operation of providing the coating agent P_PLM to the particles PT. The coating agent P_PLM may be the surfactant including the hydrophilic part HI and the hydrophobic part HB. The coating agent P_PLM used in FIG. 9B may be a positive-ion surfactant. The coating agent P_PLM may surround the surfaces of the particles PT in a micelle form.

“ST_2” may indicate an operation of providing a silica precursor to the particles PT surrounded by the coating agent P_PLM. The silica precursor may generate a silanol group through hydrolysis, and the generated silanol group may form a silica layer around the micelle surrounding the surfaces of the particles PT through a condensation reaction. In FIG. 9B, the surfaces of the particles PT may be encapsulated into a shell SHL having a micelle-silica multilayer structure.

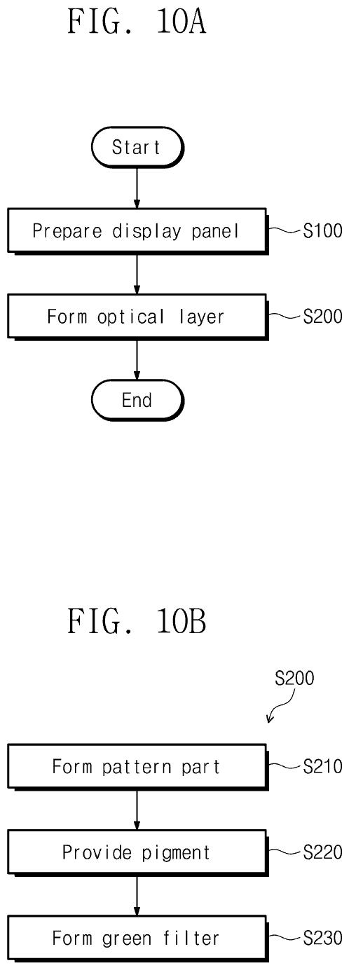

The electronic device according to an embodiment may be formed by the method of manufacturing an electronic device according to an embodiment. FIGS. 10A and 10B are flowcharts illustrating a method of manufacturing an electronic device according to an embodiment. FIGS. 11A to 11C are schematic views illustrating operations of manufacturing an electronic device according to an embodiment. Hereinafter, in the description of the method of manufacturing an electronic device according to an embodiment with reference to FIGS. 10A and 11C, contents duplicated with the contents described with reference to FIGS. 1 to 9B may not be described again, and differences therebetween will be mainly described.

Referring to FIG. 10A, the method of manufacturing an electronic device according to an embodiment may include operation S100 of preparing a display panel and operation S200 of forming an optical layer on the display panel. Referring to FIG. 10B, operation S200 of forming the optical layer may include operation S210 of forming a pattern part in which a pattern opening is defined, operation S220 of providing a pigment to the pattern opening, and operation S230 of forming a green filter.

FIGS. 11A to 11C illustrate an operation of manufacturing the green filter CF2. FIG. 11A illustrates an operation of providing the filter composition IK onto the input sensing layer ISL on the display panel DP. The filter composition IK may be directly provided onto the input sensing layer ISL. The filter composition IK may be provided in the second pattern opening P_OH2.

The filter composition IK may be provided by an inkjet printing method. FIG. 11A illustrates that the filter composition IK is provided through a nozzle NZ. However, the foregoing is by way of example, and a device providing the filter composition IK is not limited thereto.

The filter composition IK may include the green pigment PG (see FIGS. 6, 7A, and 9A). The green pigment PG (see FIGS. 6, 7A, and 9A) may include the particles PT (FIGS. 7A, 9A, and 9B) of which the surfaces are encapsulated, and the particles PT (see FIGS. 7A, 9A, and 9B) may be a phthalocyanine (PC)-based pigment including a metal element at a center thereof.

The diameter of the green pigment PG (see FIGS. 6, 7A, and 9A) may be smaller than or equal to 1 μm. For example, the diameter of the green pigment PG (see FIGS. 6, 7A, and 9A) may be smaller than or equal to 0.2 μm. The filter composition IK including the green pigment PG (see FIGS. 6, 7A, and 9A) having the diameter smaller than or equal to 1 μm may exhibit excellent discharge properties during inkjet discharge.

The filter composition IK may not contain a solvent. The solvent means a liquid for dissolving a material (e.g., a monomer, an oligomer, and/or the like) constituting a composition. The filter composition containing a solvent requires a drying time after the filter composition is applied. Unlike this, the filter composition IK not containing a solvent according to an embodiment does not utilize or require the drying time after the filter composition IK is applied and may be provided by an inkjet printing method, thereby exhibiting excellent manufacturing efficiency.

The filter composition IK may further include at least one selected from a binder, a monomer, a radical initiator, and an additive. The additive may include at least one selected from a fluorine additive and a surfactant. Each of the binder, the monomer, and the radical initiator is not limited to an embodiment and may include a material known in the art without limitation within a range that does not impair characteristics of the green filter CF2 (see FIG. 6).

FIG. 11B illustrates an operation of forming a preliminary green filter P_CF2 by applying the filter composition IK provided in the second pattern opening P_OH2. Referring to FIG. 11B, light LL may be provided on the preliminary green filter P_CF2. The light LL may be visible light having a wavelength range of 380 nm to 780 nm. For example, the light LL may be visible light having a wavelength of about 420 nm. However, the foregoing is by way of example, and an embodiment is not limited thereto. FIG. 11C illustrates an operation of forming the green filter CF2 by curing the preliminary green filter P_CF2 (see FIG. 11B) by the light LL (see FIG. 11B).

The electronic device according to an embodiment may be formed by the method of manufacturing an electronic device according to an embodiment. The method of manufacturing an electronic device according to an embodiment may include an operation of preparing a display panel and an operation of providing an optical layer onto the display panel. The operation of providing the optical layer may include an operation of providing and curing the filter composition including the particles of which surfaces are encapsulated. Accordingly, the method of manufacturing an electronic device according to an embodiment may exhibit excellent manufacturing efficiency and excellent processability.

FIG. 12 is a block diagram of an electronic device according to an embodiment. Referring to FIG. 12, the electronic device EA according to an embodiment may include the display module DM, a processor PR, a memory MR, and a power module PM. In the specification, the electronic device EA may be a display device or may include a display device. The display device may include a display module DM.

The processor PR may include at least one selected from a central processing unit (CPU), an application processor (AP), a graphic processing unit (GPU), a communication processor (CP), an image signal processor (ISP), and a controller.

Data information utilized or required for operating the processor PR or the display module DM may be stored in the memory MR. If (e.g., when) the processor PR executes an application stored in the memory MR, an image data signal and/or an input control signal may be transmitted to the display module DM, and the display module DM may process the received signal and output image information through a display screen.

The power module PM may include a power supply module such as a power adapter and/or a battery device and a power conversion module that converts power supplied by the power supply module to generate power utilized or required to operate the electronic device EA.

At least one of the components of the electronic device EA may be included in the display module DM (see FIG. 2) according to an embodiment. Further, among the components of the electronic device EA, some individual modules functionally included inside one module may be included inside the display device, and the others thereof may be provided separately from the display device. For example, the display device may include the display module DM, and the processor PR, the memory MR, and the power module PM may be provided in the form of other devices in the electronic device EA rather than the display device.

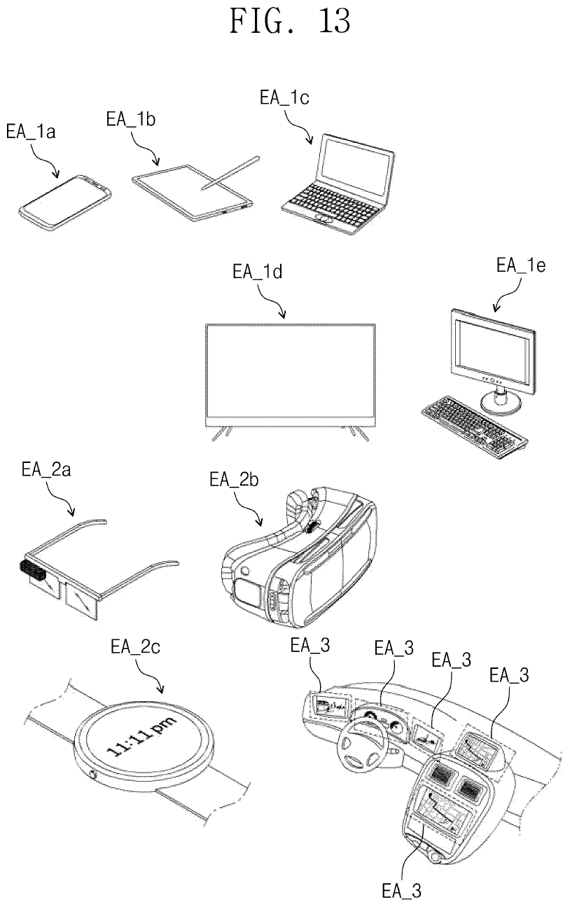

FIG. 13 is a schematic view illustrating electronic devices according to an embodiment. Referring to FIG. 13, the electronic device including the display module DM (see FIG. 2) according to an embodiment may include an image display electronic device such as a smartphone EA_1a, a tablet PC EA_1b, a laptop computer EA_1c, a television (TV) EA_1d, and/or a desk monitor EA_1e, a wearable electronic device including a display module such as a smart glasses EA_2a, a head mounted display EA_2b, and/or a smart watch EA_2c, and/or a vehicle electronic device EA_3 including a display module such as an instrument panel, a center fascia, a center information display (CID) on a dashboard, and/or a room mirror display of a vehicle.

An electronic device according to an embodiment may include a green pigment including a particle of which a surface is encapsulated, thereby exhibiting excellent light resistance and excellent color reproducibility.

A method of manufacturing an electronic device according to an embodiment may include providing a green pigment, thereby exhibiting excellent manufacturing efficiency and excellent processability.

Although the description has been made above with reference to embodiments of the present disclosure, it may be understood that those skilled in the art or those having ordinary knowledge in the art may variously suitably modify and change embodiments of the present disclosure without departing from the spirit and technical scope of the present disclosure described in the appended claims, and equivalents thereof.

Accordingly, the technical scope of the present disclosure is not limited to the detailed description of the specification, but should be defined by the appended claims, and equivalents thereof.

What is claimed is:

1. An electronic device comprising:
a display panel; and
an optical layer on the display panel,
wherein the optical layer comprises a green filter comprising a green pigment,
wherein the green pigment comprises a particle of which a surface is encapsulated, and
wherein the particle comprises a phthalocyanine (PC)-based pigment including a metal element at a center thereof.

2. The electronic device of claim 1, wherein luminance after 80 hours of light exposure is greater than or equal to 99% based on 100% initial luminance.

3. The electronic device of claim 1, wherein a diameter of the green pigment is smaller than or equal to a 1 μm.

4. The electronic device of claim 1, wherein the surface of the particle is encapsulated by an organic layer, an inorganic layer, or an organic-inorganic multi-layer structure.

5. The electronic device of claim 1, wherein the particle comprises at least one selected from pigment green 7, pigment green 36, pigment green 58, and pigment green 59.

6. The electronic device of claim 1, wherein the metal element comprises at least one selected from copper and zinc.

7. The electronic device of claim 1, wherein the optical layer further comprises:
a pattern part in which a first pattern opening, a second pattern opening, and a third pattern opening are defined;
a red filter provided in the first pattern opening; and
a blue filter provided in the third pattern opening, and
wherein the green filter is provided in the second pattern opening.

8. The electronic device of claim 7, wherein the optical layer further includes an overcoat layer on the red filter, the green filter, and the blue filter.

9. The electronic device of claim 1, further comprising:
an input sensing layer between the display panel and the optical layer.

10. The electronic device of claim 1, wherein the display panel comprises a light emitting element, and the light emitting element comprises a first electrode, a second electrode on the first electrode, and a light emitting layer between the first electrode and the second electrode.

11. The electronic device of claim 1, further comprising:
at least one selected from a processor, a memory, and a power module.

12. A method of manufacturing an electronic device, the method comprising:
providing a display panel; and
providing an optical layer comprising a green filter on the display panel,
wherein the providing of the optical layer comprises:
forming a pattern part in which a pattern opening is defined;
providing a filter composition comprising a green pigment into the pattern opening; and
forming the green filter by curing the provided filter composition,
wherein the green pigment comprises a particle of which a surface is encapsulated, and
wherein the particle comprises a phthalocyanine (PC)-based pigment comprising a metal element at a center thereof.

13. The method of claim 12, wherein the green filter is formed by an inkjet printing method.

14. The method of claim 12, wherein the filter composition does not contain a solvent.

15. The method of claim 12, wherein a diameter of the green pigment is smaller than or equal to 1 μm.

16. The method of claim 12, wherein the green pigment is formed in an emulsion polymerization method, a sol-gel process method using a micelle-silica precursor, or a ball-mill method.

17. The method of claim 12, wherein the surface of the particle is encapsulated by an organic layer, an inorganic layer, or an organic-inorganic multi-layer structure.

18. The method of claim 12, wherein the particle comprises at least one selected from pigment green 7, pigment green 36, pigment green 58, and pigment green 59.

19. The method of claim 12, wherein the filter composition further comprises at least one selected from a binder, a monomer, a radical initiator, and an additive.

20. The method of claim 19, wherein the additive comprises at least one selected from a fluorine additive and a surfactant.
